(19) United States
(12) Patent Application Publication
(10) Pub. No.: US 2003/0040158 A1
(43) Pub. Date: Feb. 27, 2003

(54) Semiconductor device and method of fabricating the same

(75) Inventor: Takehiro Saitoh, Tokyo (JP)

Correspondence Address: SCULLY SCOTT MURPHY & PRESSER, PC, 400 GARDEN CITY PLAZA, GARDEN CITY, NY, 11530

(73) Assignee: NEC Corporation, Tokyo (JP)

(21) Appl. No.: 10/224,959

(22) Filed: Aug. 21, 2002

(30) Foreign Application Priority Data
Aug. 21, 2001 (JP) 249799/2001

(51) Int. Cl. H01L 21/336

(52) U.S. Cl. 438/279

(57) ABSTRACT

A semiconductor device improves the electron mobility in the n-channel MOSFET and reduces the bend or warp of the semiconductor substrate or wafer. The fist nitride layer having a tensile stress is formed on the substrate to cover the n-channel MOSFET. The tensile stress of the first nitride layer serves to relax a compressive stress existing in the channel region. The second nitride layer having an actual compressive stress is formed on the substrate to cover the p-channel MOSFET. The first and second nitride layers serve to decrease bend or warp of the substrate. Preferably, the first nitride layer is a nitride layer of Si formed by a LPCVD process, and the second nitride layer is a nitride layer of Si formed by a PECVD process.

### BACKGROUND OF THE INVENTION

1. Field of the Invention

The present invention relates generally to semiconductor devices. More particularly, the invention relates to a semiconductor device having a n-channel Metal-Oxide-Semiconductor Field-Effect Transistor (MOSFET) and a p-channel MOSFET on a silicon (Si) substrate, and a method of fabricating the device.

2. Description of the Related Art

FIGS. 1A to 1E show the process steps of a method of fabricating a known semiconductor device having a n-channel MOSFET and a p-channel MOSFET on a single-crystal Si substrate.

First, as shown in FIG. 1A, a desired recess or recesses are formed in the surface area of a p-type single-crystal Si substrate 101 using a patterned silicon nitride (SiNₓ) layer (not shown) as a mask by a Reactive Ion Etching (RIE) process. Then, a silicon dioxide (SiO₂) layer (not shown) is grown on the surface of the substrate 101 by using a High-Density Plasma source. The surface of the substrate 101 on which the SiO₂ layer has been grown is planarized by a Chemical Mechanical Polishing (CMP) process, thereby leaving selectively the SiO₂ layer in the recess or recesses. Thus, an isolation region 102 is selectively buried in the recess or recesses in the substrate 101 to thereby form an active region in which a n-channel MOSFET (i.e., NMOS) is formed and an active region in which a p-channel MOSFET (i.e., PMOS) is formed, as shown in FIG. 1A.

Thereafter, a p-type dopant is selectively implanted into one of the active regions of the substrate 101 by an ion implantation process, thereby forming a p-type well 103 in which a n-channel MOSFET is formed. Similarly, a n-type dopant is selectively implanted into another of the active regions of the substrate 101 by an ion implantation process, thereby forming a n-type well 104 in which a p-channel MOSFET is formed. The state at this stage is shown in FIG. 1B.

A dielectric layer (not shown) for gate dielectric layers 105a and 105b is formed on the whole surface of the substrate 101 by a thermal oxidation process. A polysilicon layer (not shown) is deposited on the dielectric layer thus formed over the whole substrate 101 by a Low-Pressure Chemical Vapor Deposition (LPCVD) process. The dielectric layer and the polysilicon layer are patterned to thereby form a gate dielectric layer 105a and a gate electrode 106 on the p-type well 103 and a gate dielectric layer 105b and a gate electrode 113 on the n-type well 103. The state at this stage is shown in FIG. 1C.

Using a patterned photoresist film (not shown) and the gate electrode 106 as a mask, a n-type dopant is selectively introduced into the p-type well 103, thereby forming a n-type Lightly Doped Drain (LDD) region 108s and a n-type LDD region 108d in the well 103 at each side of the electrode 106. Similarly, using a patterned photoresist film (not shown) and the gate electrode 113 as a mask, a p-type dopant is selectively introduced into the n-type well 104, thereby forming a p-type LDD region 109s and a p-type LDD region 109d in the well 104 at each side of the electrode 113.

A SiO₂ layer (not shown) is formed on the whole surface of the substrate 101 to cover the gate electrodes 106 and 113 and then, it is patterned by a RIE process. Thus, a pair of dielectric sidewall spacers 107a is formed on the surface of the p-type well 103 at each side of the gate electrode 106 and a pair of dielectric sidewall spacers 107b is formed on the surface of the n-type well 104 at each side of the gate electrode 113.

Using a patterned photoresist film (not shown), the gate electrode 106, and the pair of sidewall spacers 107a as a mask, a n-type dopant is selectively introduced into the p-type well 103 to overlap with the n-type LDD regions 108s and 108d, thereby forming a n-type diffusion region 110s and a n-type diffusion region 110d in the well 103 at each side of the electrode 106. These p-type regions 108s and 110s serve as the source region of the n-channel MOSFET while these p-type regions 108d and 110d serve as the drain region thereof. Similarly, using a patterned photoresist film (not shown), the gate electrode 113, and the pair of sidewall spacers 107b as a mask, a p-type dopant is selectively introduced into the n-type well 104 to overlap with the p-type LDD regions 109s and 109d, thereby forming a p-type diffusion region 111s and a p-type diffusion region 111d in the well 104 at each side of the electrode 113. The n-type regions 109s and 111s serve as the source region of the p-channel MOSFET while the n-type regions 109d and hid serve as the drain region thereof. Thereafter, to activate the dopants thus introduced into the substrate 101, an annealing or heat-treatment process is carried out at approximately 1000° C. for approximately 10 seconds.

A cobalt (Co) or titanium (Ti) layer is deposited on the whole surface of the substrate 101 by a sputtering process and then, a heat-treatment process is carried out, thereby causing a silicidation reaction of the diffusion regions 110s, 110d, 111s, and 111d made of single-crystal Si and the gate electrodes 106 and 113 made of polysilicon with the Co or Ti layer thus deposited. Thus, Co or Ti silicide layers 112a, 112b, 112c, 112d, 112e, and 112f are formed. The silicide layers 112a and 112b are located in the surfaces of the diffusion regions 110s and 110d, respectively. The silicide layer 112c is located in the surface of the gate electrode 106. The silicide layers 112d and 112e are located in the surfaces of the diffusion regions 111s and 111d, respectively. The silicide layer 112f is located in the surface of the gate electrode 113. The state at this stage is shown in FIG. 1D.

Subsequently, a dielectric layer 118, which may be made of SiO₂, is formed to cover the whole surface of the substrate 101. Then, a thick interlayer dielectric layer 119, which is made of BPSG (BoroPhosphorSilicate Glass), is formed on the dielectric layer 118 by a CVD process over the whole substrate 101. The surface of the layer 119 is planarized and then, necessary contact or through holes (not shown) are formed to penetrate the layers 119 and 118. These contact holes are used for contacting the source and drain regions and the gate electrodes 106 and 113 of the n- and p-channel MOSFETs with wiring lines (not shown) to be formed on or over the layer 119. The state at this stage is shown in FIG. 1E.

Typically, tungsten (W) is used for the conductive contact plugs filled in the contact holes. Titanium (Ti) or titanium nitride (TiN) is usually used as the barrier metal along with the W plugs.

The wiring lines, which are formed on or over the layer 119 and connected to the contact plugs, are typically made of aluminum (Al) . These wiring lines of Al are typically made by depositing an Al layer by a sputtering process and pattering the Al layer thus deposited. In this way, the prior art semiconductor device 150 having the n- and p-channel MOSFETs on the substrate 101 is fabricated.

With the prior-art semiconductor device 150 shown in FIG. 1E, it was found by the inventor that compressive stress is applied to the channel regions of the n- and p-channel MOSFETs, which are respectively formed in the p-and n-type wells 103 and 104 rightly below the gate electrodes 106 and 113. Thus, a problem that the electron mobility degrades occurs. Due to this reason, the saturation drain current I_{dsat} decreases and as a result, the current driving capability deteriorates in the n-channel MOSFET. This problem is caused by the following reason.

Specifically, the n-or p-type dopant is introduced into the source regions 108s, 109s, 110s, and 111s and the drain regions 108d, 109d, 110d, and 111d. However, the concentration of the dopant is very small. Therefore, the mechanical and thermal properties of these regions 108s, 109s, 110s, 111s, 108d, 109d, 110d, and 111d are similar to those of the Si substrate 101.

The thermal expansion coefficient of Si is 3.0×10⁻⁶/° C. Unlike this, the thermal expansion coefficient of the silicide (i.e., CoSi₂ or TiSi₂) is approximately three times as much as that of Si. Polysilicon used for the gate electrodes 106 and 113 generates tensile stress due to introduction of phosphorus (P) or arsenic (As) as a dopant. Mainly because of the difference of these thermal expansion coefficients and the actual or genuine stress existing in the material, some stress occurs in the respective materials constituting the n- and p-channel MOSFETs. For example, compressive stress occurs in the channel regions just below the gate electrodes 106 and 113 of the MOSFETs.

If compressive stress exists in the channel regions, the electron mobility is decreased. Thus, the saturation drain current I_{dsat} decreases in the n-channel MOSFET which uses electrons as its carrier.

### SUMMARY OF THE INVENTION

Accordingly, an object of the present invention is to provide a semiconductor device that improves the electron mobility in the n-channel MOSFET to thereby raise its current driving capability, and a method of fabricating the device.

Another object of the present invention is to provide a semiconductor device that reduces the bend or warp of a semiconductor substrate or wafer, thereby making it possible to conduct lithography processes as desired, and a method of fabricating the device.

Still another object of the present invention is to provide a semiconductor device that reduces the possibility that a nitride layer is detached or damaged, and a method of fabricating the device.

The above objects together with others not specifically. mentioned will become clear to those skilled in the art from the following description.

According to a first aspect of the invention, a semiconductor device is provided, which comprises:

a Si substrate;

a n-channel MOSFET formed on the substrate;

a first nitride layer formed to cover the n-channel MOSFET;

the first nitride layer containing tensile stress;

a p-channel MOSFET formed on the substrate;

a second nitride layer formed to cover the p-channel MOSFET; and

the second nitride layer containing compressive stress.

With the semiconductor device according to the first aspect of the invention, the fist nitride layer having a tensile stress is formed to cover the n-channel MOSFET. Therefore, the tensile stress of the first nitride layer is applied to the corresponding surface area of the substrate, thereby decreasing the compressive stress existing in the channel region of the n-channel MOSFET. Thus, the electron mobility is increased and as a result, the current driving capability of the n-channel MOSFET is improved.

Moreover, the second nitride layer having an actual or genuine compressive stress is selectively formed to cover the p-channel MOSFET. Therefore, the compressive stress of the second nitride layer is applied to the corresponding surface are of the substrate, thereby decreasing the tensile stress existing in the channel region of the p-channel MOSFET. As a result, because of existence of the first and second nitride layers, the substrate or wafer is restrained from warping or bending. This means that lithography processes can be well conducted as desired because the warp or bend of the substrate 1 is effectively restrained.

Since the first nitride layer having an actual or genuine tensile stress is not formed on the whole surface of the substrate, the possibility that the first nitride layer is detached from the substrate and damaged is significantly decreased.

Preferably, each of the first and second nitride layers is a silicon nitride layer.

In a preferred embodiment of the device according to the first aspect of the invention, each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions. The first nitride layer covers the source/drain regions, the gate dielectric layer, the gate electrode, the sidewall spacers, and the silicide layers of the n-channel MOSFET. The second nitride layer covers the source/drain regions, the gate dielectric layer, the gate electrode, the sidewall spacers, and the silicide layers of the p-channel MOSFET.

In another preferred embodiment of the device according to the first aspect of the invention, the first nitride layer is formed by a LPCVD process.

In still another preferred embodiment of the device according to the first aspect of the invention, the second nitride layer is formed by a PECVD process.

In a further preferred embodiment of the device according to the first aspect of the invention, the n-channel MOSFET has a channel region in a surface area of the substrate. The tensile stress of the first nitride layer serves to relax a compressive stress existing in the channel region.

In a still further preferred embodiment of the device according to the first aspect of the invention, the first nitride layer and the second nitride layer serve to decrease bend or warp of the substrate.

According to a second aspect of the invention, another semiconductor device is provided, which comprises:

a Si substrate;

a n-channel MOSFET formed on the substrate;

a first nitride layer formed to cover the n-channel MOSFET;

the first nitride layer containing tensile stress;

a p-channel MOSFET formed on the substrate;

a second nitride layer formed to cover the p-channel MOSFET and the first nitride layer; and

the second nitride layer containing compressive stress.

With the semiconductor device according to second first aspect of the invention, the structure is the same as the device of the first aspect of the invention, except that the second nitride layer is formed to cover the p-channel MOSFET and the first nitride layer. Therefore, it is obvious that the same advantages as those in the device of the first embodiment are obtainable.

Preferably, each of the first and second nitride layers is a silicon nitride layer.

In a preferred embodiment of the device according to the second aspect of the invention, each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions. The first nitride layer covers the source/drain regions, the gate dielectric layer, the gate electrode, the sidewall spacers, and the silicide layers of the n-channel MOSFET. The second nitride layer covers the source/drain regions, the gate dielectric layer, the gate electrode, the sidewall spacers, and the silicide layers of the p-channel MOSFET.

In another preferred embodiment of the device according to the second aspect of the invention, the first nitride layer is formed by a LPCVD process.

In still another preferred embodiment of the device according to the second aspect of the invention, the second nitride layer is formed by a PECVD process.

In a further preferred embodiment of the device according to the second aspect of the invention, the n-channel MOSFET has a channel region in a surface area of the substrate. The tensile stress of the first nitride layer serves to relax a compressive stress existing in the channel region.

In a still further preferred embodiment of the device according to the second aspect of the invention, the first nitride layer and the second nitride layer serve to decrease bend or warp of the substrate.

According to a third aspect of the invention, a method of fabricating the semiconductor device according to the first aspect of the invention is provided. This method comprises the steps of:

forming a n-channel MOSFET and a p-channel MOSFET on a semiconductor substrate;

forming a first nitride layer over the substrate to cover the n-channel MOSFET and the p-channel MOSFET, the first nitride layer containing tensile stress;

selectively removing a part of the first nitride layer in a corresponding area to the p-channel MOSFET;

forming a second nitride layer over the substrate to cover the n-channel MOSFET and the p-channel MOSFET, the second nitride layer containing compressive stress; and

selectively removing a part of the second nitride layer in a corresponding area to the n-channel MOSFET.

With the method according to the third aspect of the invention, it is obvious that the device according to the first aspect of the invention is fabricated.

Preferably, each of the first and second nitride layers is a silicon nitride layer.

In a preferred embodiment of the method according to the third aspect of the invention, each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions. The first nitride layer covers the source/drain regions, the gate dielectric layer, the gate electrode, the sidewall spacers, and the silicide layers of the n-channel MOSFET. The second nitride layer covers the source/drain regions, the gate dielectric layer, the gate electrode, the sidewall spacers, and the silicide layers of the p-channel MOSFET.

In another preferred embodiment of the method according to the third aspect of the invention, the first nitride layer is formed by a LPCVD process.

In still another preferred embodiment of the method according to the third aspect of the invention, the second nitride layer is formed by a PECVD process.

According to a fourth aspect of the invention, a method of fabricating the semiconductor device according to the second aspect of the invention is provided. This method comprises the steps of:

forming a n-channel MOSFET and a p-channel MOSFET on a semiconductor substrate;

forming a first nitride layer over the substrate to cover the n-channel MOSFET and the p-channel MOSFET, the first nitride layer containing tensile stress;

selectively removing a part of the first nitride layer in a corresponding area to the p-channel MOSFET; and

forming a second nitride layer over the substrate to cover the n-channel MOSFET and the p-channel MOSFET, the second nitride layer containing compressive stress.

With the method according to the fourth aspect of the invention, it is obvious that the device according to the second aspect of the invention is fabricated.

Preferably, each of the first and second nitride layers is a silicon nitride layer.

In a preferred embodiment of the method according to the fourth aspect of the invention, each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions. The first nitride layer covers the source/drain regions, the gate dielectric layer, the gate electrode, the sidewall spacers, and the silicide layers of the n-channel MOSFET. The second nitride layer covers the source/drain regions, the gate dielectric layer, the gate electrode, the sidewall spacers, and the silicide layers of the p-channel MOSFET.

In another preferred embodiment of the method according to the fourth aspect of the invention, the first nitride layer is formed by a LPCVD process.

In still another preferred embodiment of the method according to the fourth aspect of the invention, the second nitride layer is formed by a PECVD process.

### BRIEF DESCRIPTION OF THE DRAWINGS

In order that the present invention may be readily carried into effect, it will now be described with reference to the accompanying drawings.

FIGS. 1A to 1E are schematic, partial cross-sectional views showing a method of fabricating a known semiconductor device, respectively.

FIG. 2 is a partial cross-sectional view showing the structure of a semiconductor device according to a first embodiment of the invention.

FIGS. 3A to 3D are schematic, partial cross-sectional views showing a method of fabricating the semiconductor device according to the first embodiment of FIG. 2, respectively.

FIG. 4 is a graph showing the improvement of the saturation drain current in the semiconductor device according to the first embodiment of FIG. 2.

FIG. 5 is a partial cross-sectional view showing the structure of a semiconductor device according to a second embodiment of the invention.

### DETAILED DESCRIPTION OF THE PREFERRED EMBODIMETNS

Preferred embodiments of the present invention will be described in detail below while referring to the drawings attached.

### First Embodiment

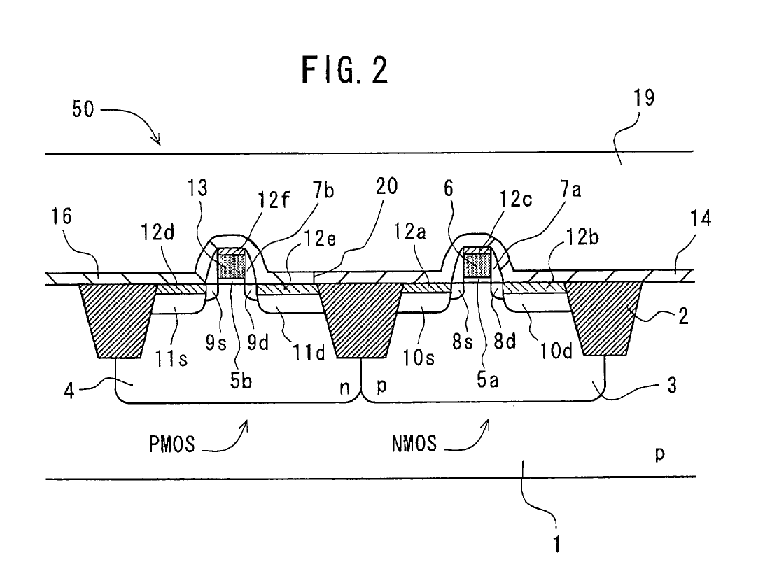

FIG. 2 shows the structure of a semiconductor device 50 having a n-channel MOSFET and a p-channel MOSFET according to a first embodiment of the invention. Actually, the device 50 comprises other n-channel MOSFETs and other p-channel MOSFETs on the same semiconductor substrate. However, one of the n-channel MOSFETs and one of the p-channel MOSFETs are shown and explained below for the sake of simplification.

As shown in FIG. 2, the semiconductor device 50 comprises a p-type single-crystal Si substrate 1 on which a n-channel MOSFET and a p-channel MOSFET are formed.

An isolation region 2 is selectively formed in a recess or recesses of the substrate 1, thereby forming an active region in which the n-channel MOSFET (i.e., NMOS) is formed and an active region in which the p-channel MOSFET (i.e., PMOS) is formed. In the active region for the n-channel MOSFET, a p-type well 3 is formed. In the active region for the p-channel MOSFET, a n-type well 4 is formed.

In the n-channel MOSFET, a polysilicon gate dielectric layer 5a is formed on the surface of the p-type well 3 and a polysilicon gate electrode 6 is formed on the layer 5a. A pair of dielectric sidewall spacers 7a is formed on the surface of the well 3 at each side of the gate electrode 6. A n-type LDD region 8s and a n-type LDD region 8d are formed in the well 3 at each side of the gate electrode 6. The regions 8s and 8d are respectively located below the corresponding sidewall spacers 7a. A n-type diffusion region 10s and a n-type diffusion region 10d are formed in the well 3 at each side of the gate electrode 6. The regions 10s and 10d are respectively located between the regions 8s and 8d and the corresponding parts of the isolation region 2. The regions 8s and 10s serve as the source region of the n-channel MOSFET while the regions 8d and 10d serve as the drain region thereof. A silicide layer 12a and a silicide layer 12b are respectively formed in the surfaces of the source and drain regions 10s and 10d. A silicide layer 12c is formed in the surface of the gate electrode 6.

In the p-channel MOSFET, a polysilicon gate dielectric layer 5b is formed on the surface of the n-type well 4 and a polysilicon gate electrode 13 is formed on the layer 5b. A pair of dielectric sidewall spacers 7b is formed on the surface of the well 4 at each side of the gate electrode 13. A p-type LDD region 9s and a p-type LDD region 9d are formed in the well 4 at each side of the gate electrode 13. The regions 9s and 9d are respectively located below the corresponding sidewall spacers 7b. A p-type diffusion region l11s and a p-type diffusion region lid are formed in the well 4 at each side of the gate electrode 13. The regions 11s and 11d are respectively located between the regions 9s and 9d and the corresponding parts of the isolation region 2. The regions 9s and 11s serve as the source region of the p-channel MOSFET while the regions 9d and 11d serve as the drain region thereof. A silicide layer 12d and a silicide layer 12e are respectively formed in the surfaces of the source and drain regions 11s and 11d. A silicide layer 12f is formed in the surface of the gate electrode 13.

A silicon nitride (SiNₓ) layer 14, which has an actual or genuine tensile stress, is selectively formed on the surface of the substrate 1 in such a way as to cover the n-channel MOSFET (i.e., the whole surface of the p-type well 3). The layer 14 is contacted with the silicide layers 12a, 12b, and 12c, the sidewall spacers 7a, the gate electrode 6, and the part of the isolation region 2. The tensile stress of the layer 14 is applied to the surface of the p-type well 3, thereby decreasing the compressive stress existing in the channel region of the n-channel MOSFET.

On the other hand, a SiNₓ layer 16, which has an actual or genuine compressive stress, is selectively formed on the surface of the substrate 1 in such a way as to cover the p-channel MOSFET (i.e., the whole surface of the n-type well 4). The layer 16 is contacted with the silicide layers 12d, 12e, and 12f, the sidewall spacers 7b, the gate electrode 13, and the part of the isolation region 2. The compressive stress of the layer 16 is applied to the surface of the n-type well 4, thereby decreasing the tensile stress existing in the channel region of the p-channel MOSFET.

The SiNₓ layers 14 and 16 are contacted with each other at a boundary 20. These layers 14 and 16 are not overlapped with each other.

A thick interlayer dielectric layer 19 made of BPSG is formed on the SiNₓ. layers 14 and 16. Necessary contact or through holes (not shown) are formed to penetrate the layer 19 and the layer 14 or 16. These contact holes are used for contacting the source and drain regions 8s, 8d, 9s, 9d, 10s, 10d, 11s, and 11d, and the gate electrodes 6 and 13 of the n- and p-channel MOSFETs with wiring lines (not shown) to be formed on or over the layer 19.

Wiring lines (not shown) are formed on or over the layer 19 in such a way as to be connected to the source and drain regions 8s, 8d, 9s, 9d, 10s, 10d, 11s, and 11d and the gate electrodes 6 and 13.

With the semiconductor device 50 according to the first embodiment of FIG. 2, the SiNₓ layer 14 having an actual tensile stress is selectively formed on the surface of the substrate 1 in such a way as to cover the n-channel MOSFET (i.e., the whole surface of the p-type well 3). Therefore, the tensile stress of the layer 14 is applied to the surface of the p-type well 3, thereby decreasing the compressive stress existing in the channel region of the n-channel MOSFET. Thus, the electron mobility (i.e., the saturation drain current) is increased and as a result, the current driving capability of the n-channel MOSFET is improved.

Moreover, the SiNₓ layer 16 having an actual compressive stress is selectively formed on the surface of the substrate 1 in such a way as to cover the p-channel MOSFET (i.e., the whole surface of the n-type well 4). Therefore, the compressive stress of the layer 16 is applied to the surface of the n-type well 4, thereby decreasing the tensile stress existing in the channel region of the p-channel MOSFET. As a result, because of existence of the SiNₓ layers 14 and 16 on the surface of the substrate 1, the substrate 1 or wafer is restrained from warping or bending. This means that lithography processes can be well conducted as desired, because the warp or bend of the substrate 1 is effectively restrained.

Since the SiNₓ, layer 14 having an actual tensile stress is not formed on the whole surface of the substrate 1, the possibility that the SiNₓ, layer 14 is detached from the substrate 1 and damaged due to its tensile stress is significantly decreased.

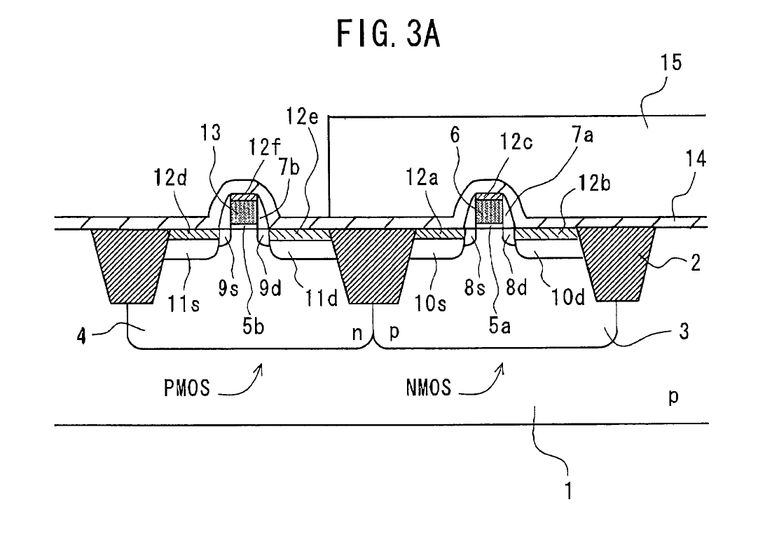

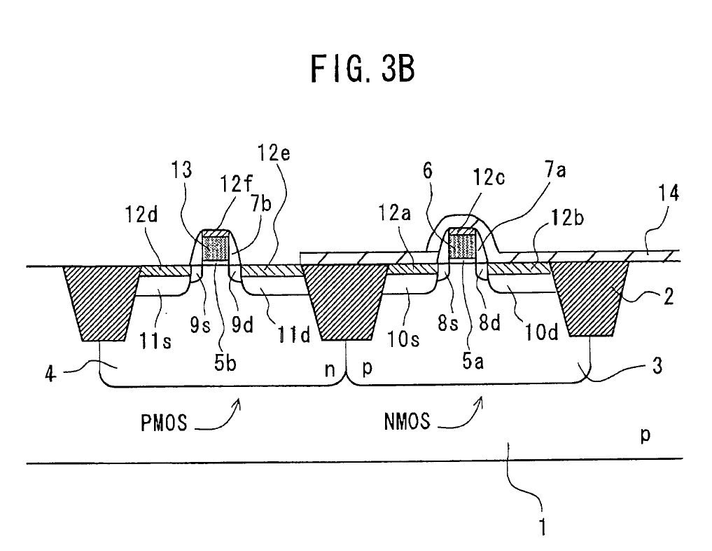

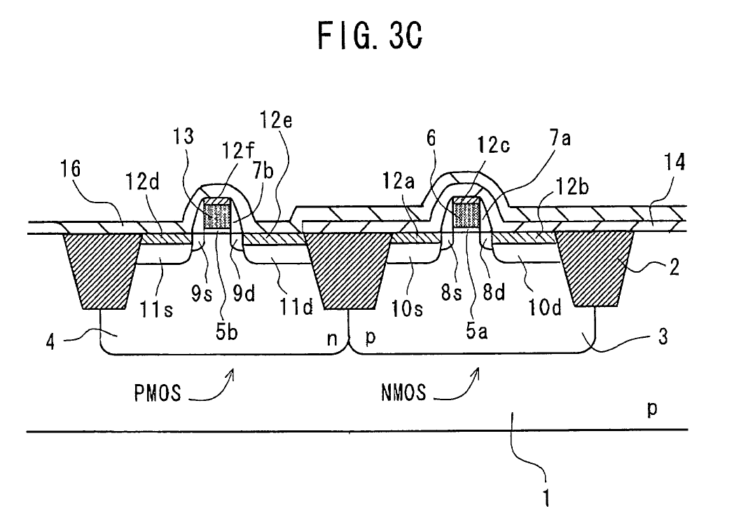

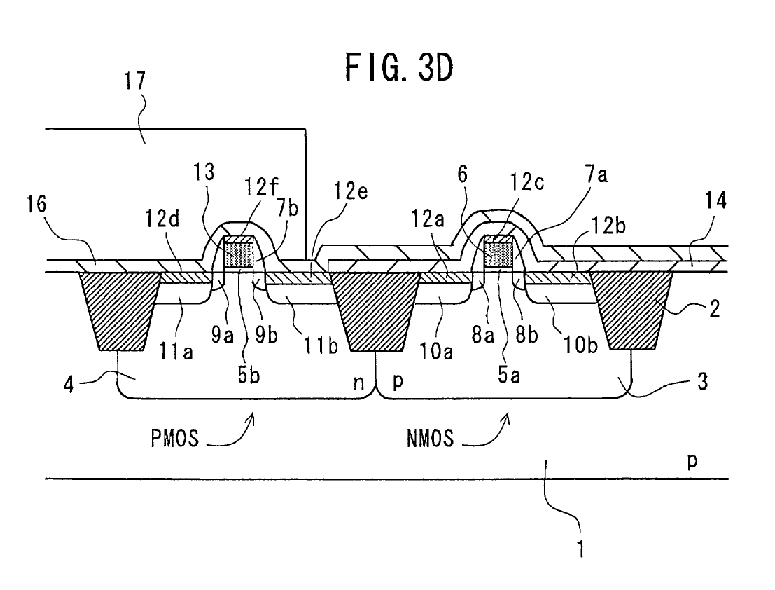

Next, a method of fabricating the semiconductor device 50 according to the first embodiment of FIG. 2 is explained below with reference to FIGS. 3A to 3D.

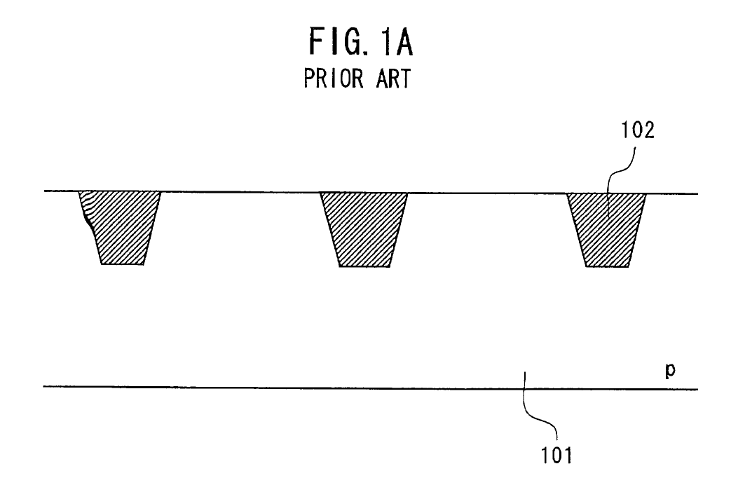

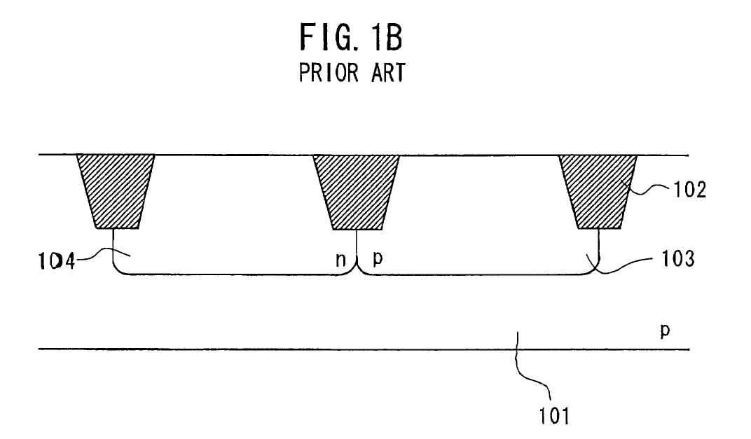

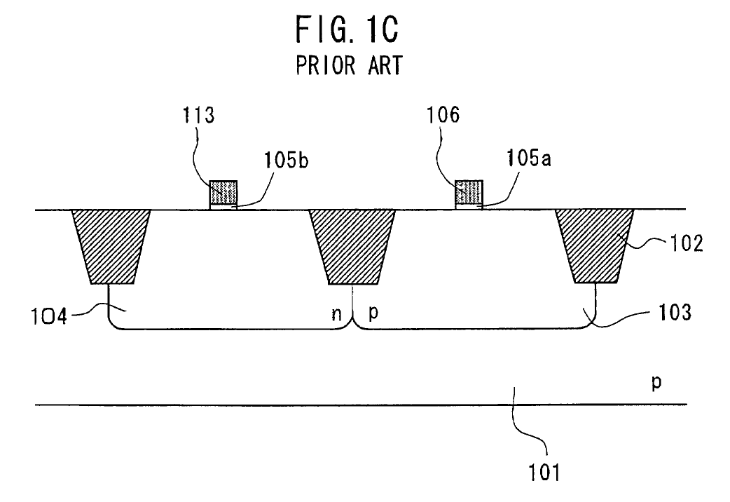

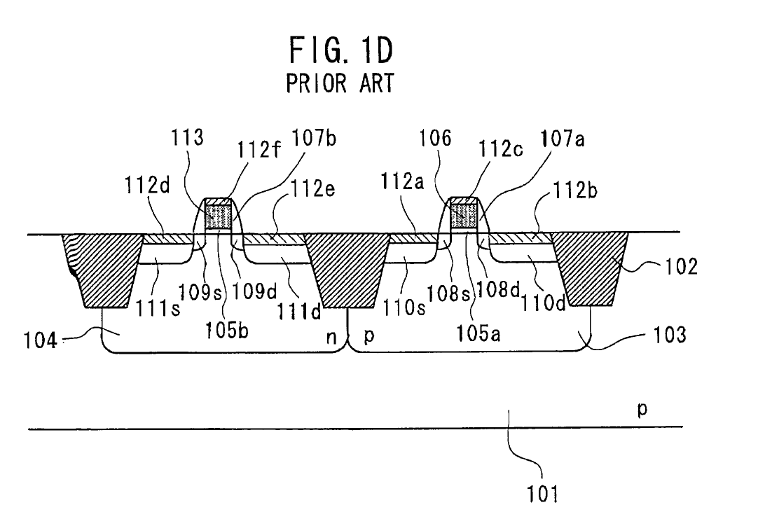

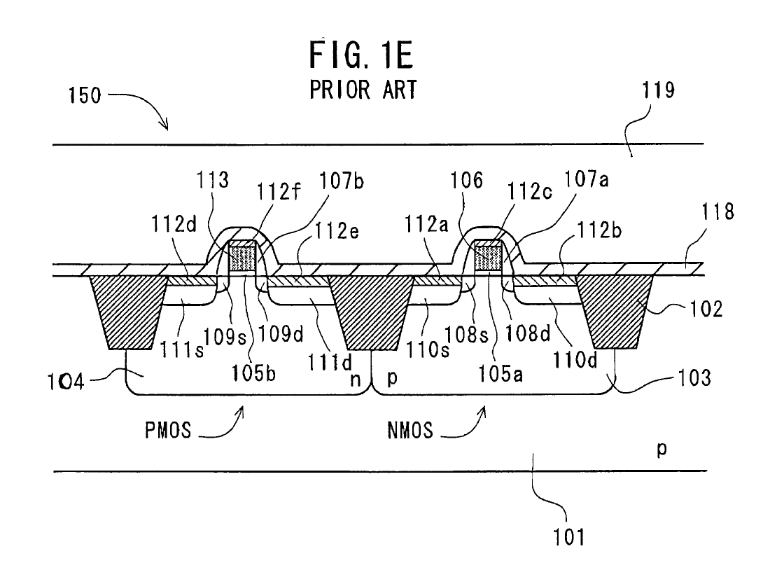

First, as shown in FIG. 3A, the n- and p-channel MOSFETs are formed through the same process steps as those in the prior-art method shown in FIGS. 1A to 1D.

Specifically, a desired recess or recesses are formed in the surface area of the p-type single-crystal Si substrate 1 and then, a SiO₂ layer (not shown) is left selectively in the recess or recesses, thereby forming the isolation region 2. Thereafter, the p-type well 3 for the n-channel MOSFET and the n-type well 104 for the p-channel MOSFET are formed. A dielectric layer and a polysilicon layer are successively formed on the substrate 1 and patterned, thereby forming the gate dielectric layer 5a and the gate electrode 6 on the p-type well 3 and the gate dielectric layer 5b and the gate electrode 13 on the n-type well 4.

Thereafter, the n-type LDD regions 8s and 8d are formed in the p-type well 3, the pair of dielectric sidewall spacers 7a is formed on the surface of the well 3, and the n-type diffusion regions 10s and 10d are formed in the well 3. Similarly, the p-type LDD regions 9s and 9d are formed in the n-type well 4, the pair of dielectric sidewall spacers 7b is formed on the surface of the well 4, and the p-type diffusion regions 11s and l11d are formed in the well 4. To activate the p- and n-type dopants thus introduced into the substrate 1, a specific annealing or heat-treatment process is carried out.

Subsequently, the silicide layers 12a, 12b, 12c, 12d, 12e, and 12f of Co or Ti are formed through a silicidation reaction. The silicide layers 12a and 12b are located in the surfaces of the diffusion regions 10s and 10d, respectively. The silicide layer 12c is located in the surface of the gate electrode 6. The silicide layers 12d and 12e are located in the surfaces of the diffusion regions 11s and 11d, respectively. The silicide layer 12f is located in the surface of the gate electrode 13.

The following process steps are different from the above-described prior-art method.

Following the silicidation process for the silicide layers 12a, 12b, 12c, 12d, 12e, and 12f of Co or Ti, the SiNₓ layer 14 having an actual tensile stress is formed on the whole surface of the substrate 1 in such a way as to cover the n- and p-channel MOSFETs by a LPCVD process. Then, a patterned photoresist film 15 is formed on the SiNₓ layer 14 thus formed. The film 15 exposes selectively the area corresponding to the p-channel MOSFET and other necessary areas. The state at this stage is shown in FIG. 3A.

Next, using the patterned photoresist film 15 as a mask, the SiNₓ layer 14 is selectively removed by an etching process, as shown in FIG. 3B. Thus, the surface of the n-type well 4 and the other necessary areas are exposed from the layer 14. The film 15 is then removed from the substrate 1.

Subsequently, the SiNₓ layer 16 having an actual compressive stress is formed on the SiNₓ layer 14 to cover the whole surface of the substrate 1, as shown in FIG. 3C, by a Plasma-Enhanced CVD (PECVD) process. In the PECVD process, hydrogen (H) is introduced into the film 16 and as a result, an actual compressive stress is generated in the film 16. Thus, any PECVD process is preferred for this purpose if H is introduced into the film 16. The layer 16 is contacted with the SiNₓ layer 14 and the top of the p-channel MOSFET. The state at this stage is shown in FIG. 3C.

Then, a patterned photoresist film 17 is formed on the SiNₓ layer 16, as shown in FIG. 3D. The film 17 exposes selectively the area corresponding to the n-channel MOSFET and other necessary areas. The state at this stage is shown in FIG. 3D. Using the patterned photoresist film 17 as a mask, the SiNₓ layer 16 is selectively removed by a plasma etching process. Thus, the underlying SiNₓ layer 14 is selectively exposed in the surface of the p-type well 4 and the other necessary areas, as shown in FIG. 2. The SiNₓ layers 14 and 16 are contacted with each other at the boundary 20. The film 17 is then removed from the substrate 1.

Thereafter, the thick interlayer dielectric layer 19 of BPSG is formed on the SiNₓ layers 14 and 16 by a known process such as CVD. Necessary contact or through holes (not shown) are formed by a known etching method to penetrate the layer 19 and the layer 14 or 16 in such a way as to reach the source and drain regions 8s, 8d, 9s, 9d, 10s, 10d, 11s, and 11d, and the gate electrodes 6 and 13 of the n- and p-channel MOSFETs. The surface of the layer 19 is then planarized.

Finally, necessary wring lines (not shown) are formed on or over the layer 19 in such a way as to be connected to the source and drain regions 8s, 8d, 9s, 9d, 10s, 10d, 11s, and 11d and the gate electrodes 6 and 13. Thus, the semiconductor device 50 according to the first embodiment of FIG. 2 is fabricated.

Next, the operation of the device 50 of the first embodiment is explained below.

Although the n-or p-type dopant is introduced into the source regions 8s, 9s, 10s, and 11s and the drain regions 8d, 9d, 10d, and lid, the concentration of the dopant is very small. Thus, the mechanical and thermal properties of these regions 8s, 9s, 10s, 11s, 8d, 9d, 10d, and lid are similar to those of the Si substrate 1. The thermal expansion coefficient of Si is 3.0×10⁻⁶/° C. and the thermal expansion coefficient of the silicide (i.e., CoSi₂ or TiSi₂) is approximately three times as much as that of Si. Polysilicon used for the gate electrodes 6 and 13 generates tensile stress due to introduction of a p- or n-type dopant such as phosphorus (P) or arsenic (As) . Mainly because of the difference of these thermal expansion coefficients and the actual stress in the material, stress occurs in the respective materials constituting the n- and p-channel MOSFETs.

With the device 50 of the first embodiment, since the SiNₓ layer 14 having an actual tensile stress is selectively formed on the surface of the substrate 1 in such a way as to cover the n-channel MOSFET, the tensile stress of the layer 14 is applied to the surface of the p-type well 3, thereby decreasing the compressive stress existing in the channel region of the n-channel MOSFET. Thus, the electron mobility is increased and as a result, the current driving capability of the n-channel MOSFET is improved.

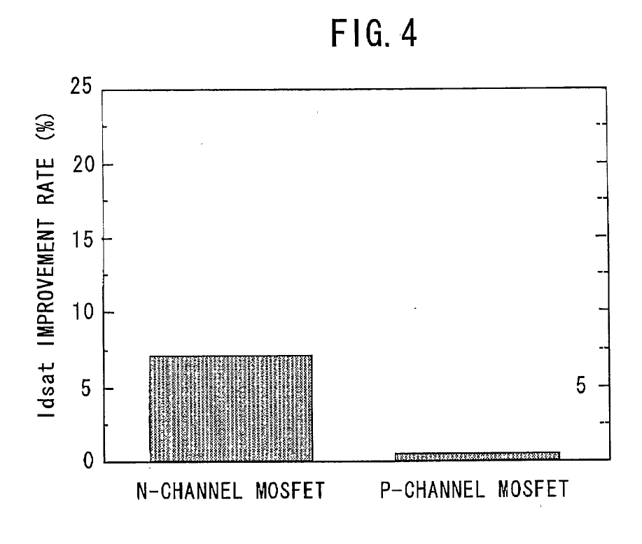

FIG. 4 shows the improvement rate of the saturation drain current I_{dsat} of the n- and p-channel MOSFETs in the device 50 compared with the prior-art device 150 shown in FIG. 1E, which was obtained by the inventor's test. As seen from FIG. 4, the saturation drain current I_{dsat} of the n-channel MOSFET in the device 50 is significantly improved by approximately 7%. This is because the carrier in the n-channel MOSFET is electron. On the other hand, the saturation drain current I_{dsat} of the p-channel MOSFET in the device 50 is improved by a slight value, which is due to the fact that “holes” are used as the carrier in the p-channel MOSFET.

### Second Embodiment

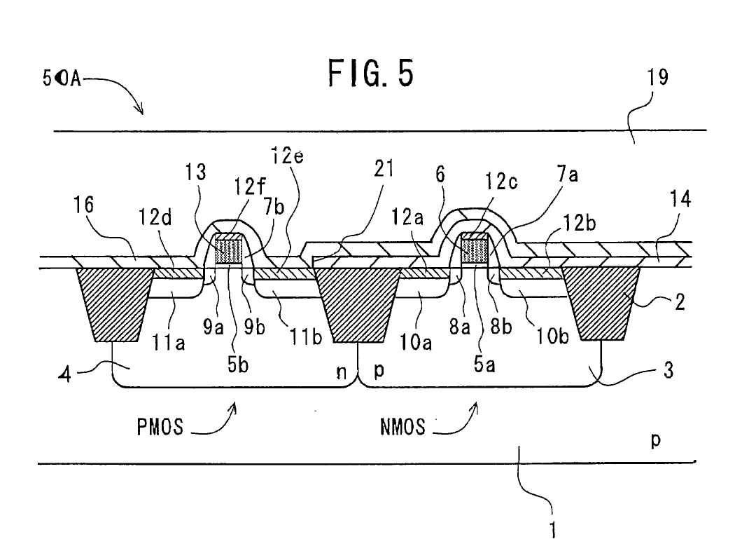

FIG. 5 shows the structure of a semiconductor device 50A having a n-channel MOSFET and a p-channel MOSFET according to a second embodiment of the invention. This device 50A has the same structure as the device 50 of the first embodiment except that the SiNₓ layer 16 having an actual compressive stress is formed to cover the whole surface of the substrate 1. Therefore, the explanation on the same structure is omitted here for the sake of simplification by attaching the same reference symbols as those used in the first embodiment.

As seen from FIG. 5, the SiNₓ layer 16 is placed on the SiNₓ layer 14 in the area just above the n-channel-MOSFET. In other words, the layer 16 is overlapped with the underlying layer 14.

A method of fabricating the semiconductor device 50A according to the second embodiment of FIG. 5 is explained below.

First, as shown in FIG. 3A, the n- and p-channel MOSFETs are formed through the same process steps as those in the prior-art method shown in FIGS. 1A to 1D.

Following the silicidation process for the silicide layers 12a, 12b, 12c, 12d, 12e, and 12f of Co or Ti, the SiNₓ layer 14 having an actual tensile stress is formed on the whole surface of the substrate 1 in such a way as to cover the n- and p-channel MOSFETs by a LPCVD process. Then, a patterned photoresist film 15 is formed on the SiNₓ layer 14 thus formed. The film 15 exposes selectively the area corresponding to the p-channel MOSFET and other necessary areas. The state at this stage is shown in FIG. 3A.

Next, using the patterned photoresist film 15 as a mask, the SiNₓ layer 14 is selectively removed by an etching process, as shown in FIG. 3B. Thus, the surface of the n-type well 4 and the other necessary areas are exposed. The film 15 is then removed from the substrate 1.

Subsequently, the SiNₓ layer 16 having an actual compressive stress is formed on the SiNₓ layer 14 to cover the whole surface of the substrate 1, as shown in FIG. 3C by a PECVD process. The layer 16 is overlapped with the layer 14.

The above-identified process steps are the same as those in the first embodiment.

Thereafter, without forming the patterned photoresist film 17 and without etching the SiNₓ layer 16, the thick interlayer dielectric layer 19 of BPSG is formed on the SiNₓ layer 16 by a known process such as CVD. The surface of the layer 19 is then planarized.

The following process steps are the same as those in the first embodiment.

With the semiconductor device 50A according to the second embodiment of FIG. 5, the same advantages as those in the device 50 of the first embodiment are obtainable. Specifically, the electron mobility in the channel region is increased and as a result, the current driving capability of the n-channel MOSFET is improved. Moreover, the substrate 1 or wafer is restrained from warping or bending, which means that lithography processes can be well conducted as desired, because the warp or bend of the substrate 1 is effectively restrained. The possibility that the SiNₓ layer 14 is detached from the substrate 1 and damaged is significantly decreased.

The processes of forming the patterned photoresist film 17 and etching the SiNₓ layer 16 are unnecessary in the fabrication method of the device 50A of the second embodiment. Therefore, the device 50A has an additional advantage that the fabrication cost is lower than the device 50 of the first embodiment, because the count of the necessary process steps is decreased compared with the first embodiment.

### Variations

Needless to say, the present invention is not limited to the above-described first and second embodiments, because these embodiments are preferred examples of the invention. Any change or modification may be added to them within the spirit of the invention.

While the preferred forms of the present invention have been described, it is to be understood that modifications will be apparent to those skilled in the art without departing from the spirit of the invention. The scope of the present invention, therefore, is to be determined solely by the following claims.

What is claimed is:

1. A semiconductor device comprising:
a Si substrate;
a n-channel MOSFET formed on the substrate;
a first nitride layer formed to cover the n-channel MOSFET;
the first nitride layer containing tensile stress;
a p-channel MOSFET formed on the substrate;
a second nitride layer formed to cover the p-channel MOSFET; and
the second nitride layer containing compressive stress.

2. The device according to claim 1, wherein each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions;
and wherein the first nitride layer covers the source/drain regions, the gate dielectric layer, the gate electrode, the sidewall spacers, and the silicide layers of the n-channel MOSFET;
and wherein the second nitride layer covers the source/drain regions, the gate dielectric layer, the gate electrode, the sidewall spacers, and the silicide layers of the p-channel MOSFET.

3. The device according to claim 1, wherein the first nitride layer is formed by a LPCVD process.

4. The device according to claim 1, wherein the second nitride layer is formed by a PECVD process.

5. The device according to claim 1, wherein the n-channel MOSFET has a channel region in a surface area of the substrate;
and wherein the tensile stress of the first nitride layer serves to relax a compressive stress existing in the channel region.

6. The device according to claim 1, wherein the first nitride layer and the second nitride layer serve to decrease bend or warp of the substrate.

7. A semiconductor device comprising:
a Si substrate;
a n-channel MOSFET formed on the substrate;
a first nitride layer formed to cover the n-channel MOSFET;
the first nitride layer containing tensile stress;
a p-channel MOSFET formed on the substrate;
a second nitride layer formed to cover the p-channel MOSFET and the first nitride layer; and
the second nitride layer containing compressive stress.

8. The device according to claim 7, wherein each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions;
and wherein the first nitride layer covers the source/drain regions, the gate dielectric layer, the gate electrode, the sidewall spacers, and the silicide layers of the n-channel MOSFET;
and wherein the second nitride layer covers the source/drain regions, the gate dielectric layer, the gate electrode, the sidewall spacers, and the silicide layers of the p-channel MOSFET.

9. The device according to claim 7, wherein the first nitride layer is formed by a LPCVD process.

10. The device according to claim 7, wherein the second nitride layer is formed by a PECVD process.

11. The device according to claim 7, wherein the n-channel MOSFET has a channel region in a surface area of the substrate;
and wherein the tensile stress of the first nitride layer serves to relax a compressive stress existing in the channel region.

12. The device according to claim 7, wherein the first nitride layer and the second nitride layer serve to decrease bend or warp of the substrate.

13. A method of fabricating a semiconductor device, comprising the steps of:
forming a n-channel MOSFET and a p-channel MOSFET on a semiconductor substrate;
forming a first nitride layer over the substrate to cover the n-channel MOSFET and the p-channel MOSFET, the first nitride layer containing tensile stress;
selectively removing a part of the first nitride layer in a corresponding area to the p-channel MOSFET;
forming a second nitride layer over the substrate to cover the n-channel MOSFET and the p-channel MOSFET, the second nitride layer containing compressive stress; and
selectively removing a part of the second nitride layer in a corresponding area to the n-channel MOSFET.

14. The method according to claim 13, wherein each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions;
and wherein the first nitride layer covers the source/drain regions, the gate dielectric layer, the gate electrode, the sidewall spacers, and the silicide layers of the n-channel MOSFET;
and wherein the second nitride layer covers the source/drain regions, the gate dielectric layer, the gate electrode, the sidewall spacers, and the silicide layers of the p-channel MOSFET.

15. The method according to claim 13, wherein the first nitride layer is formed by a LPCVD process.

16. The method according to claim 13, wherein the second nitride layer is formed by a PECVD process.

17. A method of fabricating a semiconductor device, comprising the steps of:
forming a n-channel MOSFET and a p-channel MOSFET on a semiconductor substrate;
forming a first nitride layer over the substrate to cover the n-channel MOSFET and the p-channel MOSFET, the first nitride layer containing tensile stress;
selectively removing a part of the first nitride layer in a corresponding area to the p-channel MOSFET; and
forming a second nitride layer over the substrate to cover the n-channel MOSFET and the p-channel MOSFET, the second nitride layer containing compressive stress.

18. The method according to claim 17, wherein each of the n-channel MOSFET and the p-channel MOSFETs comprises source/drain regions, a gate dielectric layer, a gate electrode, sidewall spacers, and silicide layers formed in a top of the gate electrode and in surfaces of the source/drain regions;
and wherein the first nitride layer covers the source/drain regions, the gate dielectric layer, the gate electrode, the sidewall spacers, and the silicide layers of the n-channel MOSFET;
and wherein the second nitride layer covers the source/drain regions, the gate dielectric layer, the gate electrode, the sidewall spacers, and the silicide layers of the p-channel MOSFET.

19. The method according to claim 17, wherein the first nitride layer is formed by a LPCVD process.

20. The method according to claim 17, wherein the second nitride layer is formed by a PECVD process.
